(19) United States
(12) Patent Application Publication
(10) Pub. No.: US 2025/0087481 A1
(43) Pub. Date: Mar. 13, 2025

(54) INCREASING DEPOSITION RATES OF OXIDE FILMS

(71) Applicant: LAM RESEARCH CORPORATION, Fremont, CA (US)

(72) Inventors: Awnish Gupta, Hillsboro, OR (US); Frank L. Pasquale, Beaverton, OR (US); Adrien Lavoie, Newberg, OR (US); Shiva Sharan Bhandari, Tualatin, OR (US); Pulkit Agarwal, Beaverton, OR (US); Bart Jan van Schravendijk, Palo Alto, CA (US)

(21) Appl. No.: 18/580,603

(22) PCT Filed: Jun. 24, 2022
(86) PCT No.: PCT/US2022/034962

§ 371 Date: Jan. 18, 2024

Related U.S. Application Data
(60) Provisional application No. 63/223,524, filed on Jul. 19, 2021.

(51) Int. Cl. H01L 21/02; C23C 16/455; C23C 16/52

(52) U.S. Cl. CPC H01L 21/0228; C23C 16/45538; C23C 16/52; H01L 21/02164; H01L 21/02274

(57) ABSTRACT

Various embodiments include a method for increasing a deposition rate of, for example, an atomic-layer deposition (ALD)-produced film onto a surface of a substrate. In one exemplary embodiment, the method includes placing the substrate in a deposition chamber, introducing a precursor gas into the deposition chamber, evacuating at least a portion of remaining precursor-gas molecules from the deposition chamber, applying a radio-frequency (RF) conversion to the substrate in the deposition chamber, performing a plasma-species RF purge, and introducing a hydrogen (Fh) gas into the deposition chamber during one or more of the operations including introducing the precursor gas into the deposition chamber, evacuating at least the portion of remaining precursor-gas molecules from the deposition chamber, applying the RF conversion step to the substrate in the deposition chamber, and performing the plasma-species RF purge. Other methods are disclosed.

### CLAIM OF PRIORITY

This application claims the benefit of priority to U.S. Patent Application Ser. No. 63/223,524, filed on Jul. 19, 2021, which is incorporated by reference herein in its entirety.

### TECHNOLOGY FIELD

The disclosed subject matter is generally related to the field of depositing films on substrates. More specifically, the disclosed subject matter is related to increasing a deposition rate of atomic-layer deposition (ALD) films on a substrate (e.g., such as a semiconductor-based wafer in general or a silicon wafer in particular).

### BACKGROUND

Contemporaneous atomic-layer deposition sequences follow the traditional precursor-purge-oxidation-purge sequence. Efforts to modify resultant properties of films (e.g., deposition rates, in-feature deposition rates, step coverage, etc.) deposited with an ALD process scheme generally lead to trade-offs with, for example, an adverse effect on throughput of semiconductor substrates.

The information described in this section is provided to offer the skilled artisan a context for the following disclosed subject matter and should not be considered as admitted prior art.

### SUMMARY

An embodiment of the disclosed subject matter describes a method for increasing a deposition rate of an atomic-layer deposition (ALD)-produced film onto a surface of a substrate. The method includes placing the substrate in a deposition chamber; introducing a precursor gas into the deposition chamber; evacuating at least a portion of remaining precursor-gas molecules from the deposition chamber; applying a radio-frequency (RF) conversion to the substrate in the deposition chamber; performing a plasma-species RF purge; and introducing a hydrogen (H₂) gas into the deposition chamber during one or more of introducing the precursor gas into the deposition chamber, evacuating at least the portion of remaining precursor-gas molecules from the deposition chamber, applying the RF conversion step to the substrate in the deposition chamber, and performing the plasma-species RF purge.

Another embodiment of the disclosed subject matter describes a method for increasing a deposition rate of an atomic-layer deposition (ALD)-produced oxide film on a substrate. The method includes placing the substrate in a deposition chamber; introducing a precursor gas into the deposition chamber; evacuating at least a portion of remaining precursor-gas molecules from the deposition chamber; applying a radio-frequency (RF) conversion to the substrate in the deposition chamber; performing a plasma-species RF purge; and introducing hydrogen (H₂) gas into the deposition chamber as an H₂ co-flow gas during at least one of the applying of the RF conversion and the performing of the plasma-species RF purge.

Another embodiment of the disclosed subject matter describes a method for increasing a deposition rate of an atomic-layer deposition (ALD)-produced silicon dioxide film on a substrate. The method includes placing the substrate in a deposition chamber; introducing a precursor gas into the deposition chamber; evacuating at least a portion of remaining precursor-gas molecules from the deposition chamber; applying a radio-frequency (RF) conversion to the substrate in the deposition chamber; performing a plasma-species RF purge; and introducing a hydrogen (H₂) gas into the deposition chamber only during the applying of the RF conversion.

### BRIEF DESCRIPTION OF FIGURES

FIG. 1A shows an example of a graph of deposition rate as a function of dose time, comparing a standard Argon-based (Ar-based) process during an ALD oxidation step and with an Ar-plus hydrogen-based (H₂-based) process step added during an ALD oxidation step in accordance with various exemplary embodiments of the disclosed subject matter;

FIG. 1B shows an example of a graph of a percentage of deposition rate increase with H₂ gas added as a function of dose time in accordance with various embodiments of the disclosed subject matter;

FIG. 2A shows an example of various steps in an ALD oxidation process selected for an addition of H₂ gas to increase a deposition rate in accordance with various embodiments of the disclosed subject matter;

FIG. 2B shows an example of a graph of deposition rate as a function of process steps selected in FIG. 2A;

FIG. 3 shows an example of a graph of a bivariate fit of thickness of a film as a function of flowrate of H₂ gas during a radio-frequency (RF) conversion step in an oxidation process;

FIG. 4A shows an example of a cross-sectional view of a semiconductor structure used to determine a wet-etch rate ratio (WERR) improvement due to an addition of H₂ gas;

FIGS. 4B and 4C show examples of graphs of WERR at various positions within the semiconductor structure of FIG. 4A, the graphs compare a standard plasma-enhanced ALD (PEALD) process with an H₂-gas co-flow ALD process performed at temperatures of 400° C. and 650° C., respectively;

FIGS. 5A and 5B show examples of sub-conformal and super-conformal step-coverage cross-sectional drawings, respectively;

FIG. 5C shows examples of graphs of normalized step coverage at various positions within the semiconductor structure of FIG. 4A; the graphs compare an H₂-gas co-flow ALD process with a standard PEALD process, both graphs being constructed based on a deposition pedestal temperature of 400° C.;

FIG. 5D shows an exemplary graph of super-conformal and sub-conformal step coverage as a function of a standard ALD process and various amounts of an H₂-gas co-flow ALD process in a gapfill operation; and

FIG. 6 shows an exemplary method for conducting an ALD oxidation process using an H₂-gas co-flow.

### DETAILED DESCRIPTION

The description that follows includes illustrative examples, devices, and apparatuses that embody various aspects of the disclosed subject matter. In the following description, for purposes of explanation, numerous specific details are set forth in order to provide an understanding of various embodiments of the inventive subject matter. It will be evident however, to those of ordinary skill in the art, that various embodiments of the disclosed subject matter may be practiced without these specific details. Further, well-known structures, materials, and techniques have not been shown in detail, so as not to obscure the various illustrated embodiments.

Various exemplary embodiments discussed herein below focus on increasing a deposition rate of atomic-layer deposition (ALD) oxide film deposition by greater than about 10% with an addition of hydrogen (H₂) gas chemistry added during an oxidation step as compared with no H₂ gas added. The disclosed subject matter also lists other physical property changes from the H₂-gas chemistry (e.g., improvement of in-feature wet-etch rate ratios (WERRs) and step-coverage changes). Various embodiments of the disclosed subject matter are detailed herein along with related models and a resulting determination that the increase in the deposition rate is a result of the chemistry change during an oxidation step in the ALD cycle.

Various embodiments of the disclosed solution utilize an addition of H₂-gas chemistry during a plasma-based oxidation step of the ALD process to, for example, increase a deposition rate. The increase in the deposition rate occurs without degrading film properties. In general, ALD processes have several advantages over other deposition processes (e.g., a chemical vapor deposition (CVD) process) for thin films (in various embodiments, the thin films referred to herein may comprise films that are typically less than about 100 nm in thickness). At least some of the advantages are due to a lower deposition rate per unit of time for the ALD process. For a given set of deposited-film properties (e.g., in-feature WERRs), increasing deposition rates of ALD films enables cost advantages over thicker films. The disclosed subject matter is applicable to both low aspect-ratio (low AR) and high AR features, and as such is applicable in, for example, silicon dioxide (SiO₂) layers in various electronic devices such as, for example, non-volatile memory devices (e.g., NAND flash memory), dynamic random-access memory (DRAM) devices, logic devices, and other emerging memory and logic-device applications.

Further, although various embodiments describe forming an SiO₂ layer, the disclosed subject matter is not limited to only SiO₂ (or SiₓO_{y} in general). Therefore, the disclosed subject matter may be used with various types of Group IVa oxides or other oxides including, for example, tantalum pentoxide (Ta₂O₅), aluminum oxide (Al₂O₃), hafnium oxide (HfO₂), zirconium dioxide (ZrO₂), lanthanum oxide (LaₓO_{y}), strontium titanate (SrTiO₃), strontium oxide (SrO), or combinations of these and other dielectric materials.

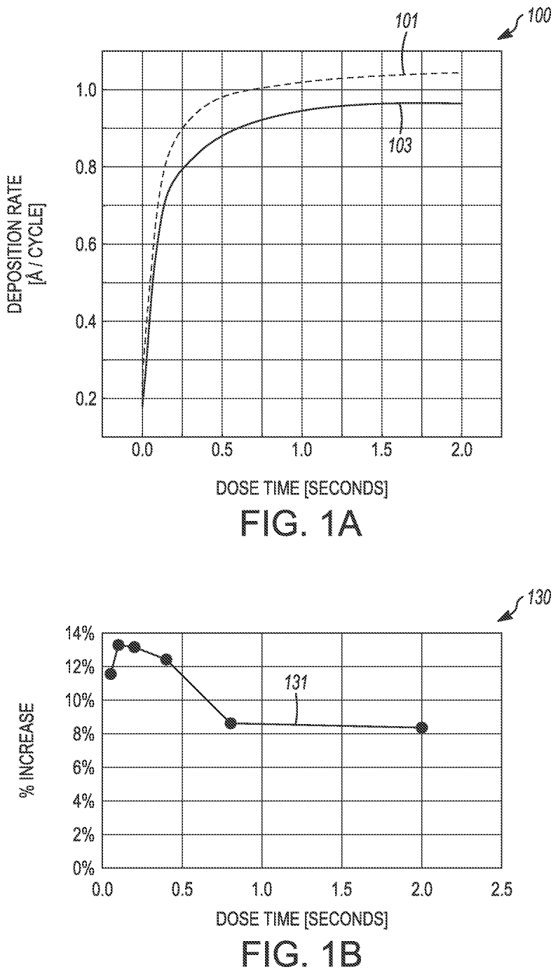

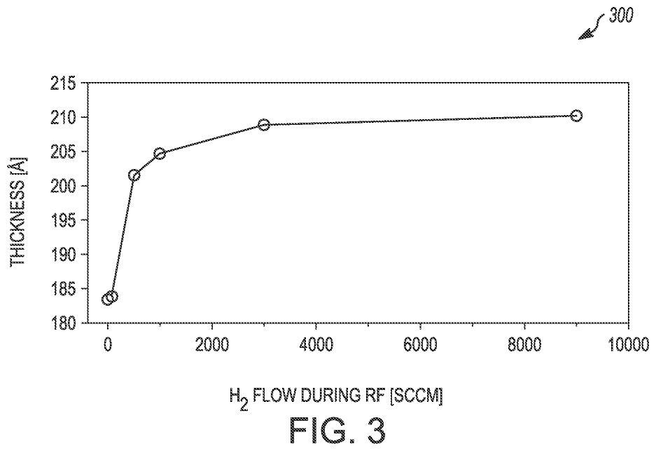

With reference to FIG. 1A, an example of a graph 100 of deposition rate as a function of dose time, comparing a standard Argon-based (Ar-based) process during an ALD oxidation step and with an Ar plus hydrogen-based (Ar plus H₂-based) process step added during an ALD oxidation step in accordance with various exemplary embodiments of the disclosed subject matter is shown. Actual exemplary flowrates of the added H₂ gas are discussed with reference to FIG. 3, below.

The graph 100 of deposition rate indicates an ALD deposition rate (in units of Angstroms (Å) per cycle) as a function of dose time (in seconds). As indicated by the graph 100, a curve 103 of a deposition rate of an Argon-only process is significantly lower than indicated by a curve 101 of a deposition rate of an Argon plus Hydrogen process. For example, starting at a dose time of approximately 0.25 seconds, the graph 100 indicates that the deposition rate of the curve 101 of the Ar—H₂ process is more than 10% higher than the curve 103 of the Ar-only process. In various examples described in more detail below, the ALD deposition rate is improved by approximately 10% to about 15% when adding H₂ gas to the ALD deposition process. Although not shown explicitly, the ALD increase shown in graph 100 was repeatable for both the Ar-based process and the Ar plus H₂-based process over a number of deposition stations. In this particular example, a temperature of the pedestal supporting the substrate undergoing the ALD deposition process was about 400° C., using a silicon dioxide precursor gas, such as silanediamine or other silicon dioxide precursor gas known in the art, with an applied radio-frequency (RF) power of 5000 W for 0.25 seconds. However, upon reading and understanding the disclosed subject matter, a person of ordinary skill in the art will recognize that the gases, powers, and times provided herein are exemplary only and many other combinations may be used as well.

FIG. 1B shows an example of a graph 130 of a percentage of deposition rate increase with H₂ gas added as a function of dose time in accordance with various embodiments of the disclosed subject matter. The graph 130 indicates that a percentage increase as a function of dose time (in seconds) is initially greater than about 11% (to over about 13% during a dose time in the first 0.5 seconds). The curve 131 is essentially flat at over about 8% after approximately 0.7 seconds.

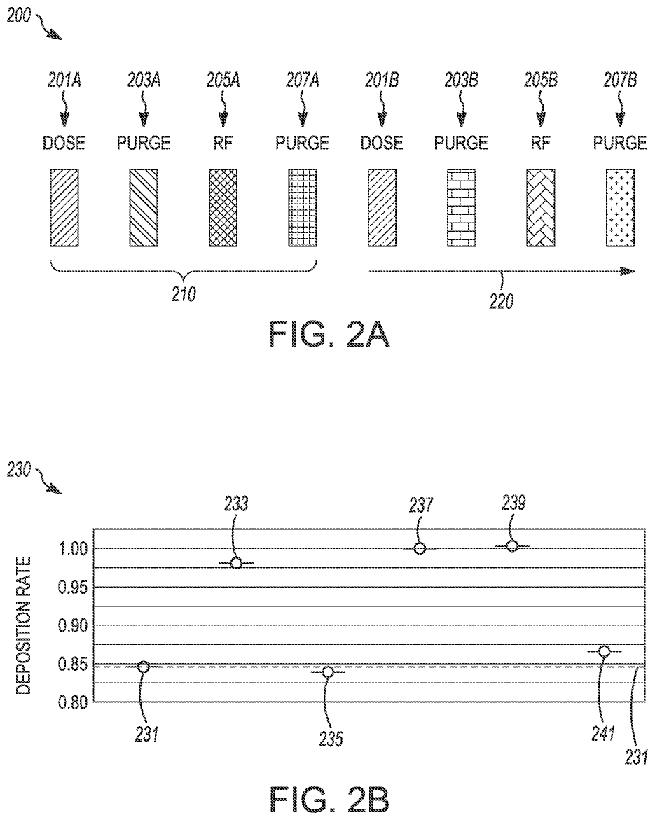

FIG. 2A shows an example of various steps in an ALD oxidation process 200 selected for an addition of H₂ gas to increase a deposition rate in accordance with various embodiments of the disclosed subject matter. As is known to a person of ordinary skill in the art, in an ALD process, a thin-film may be deposited based on a sequential use of gas-phase precursors (e.g., reactant gases). The precursor gases react with a surface of a material (e.g., a substrate such as a semiconductor-based wafer) one at a time in a sequential operation. For example, in an ALD process, a number of deposition steps 210 may be repeated 220 (possibly with a different precursor gas or gases) numerous times to arrive at a final desired film thickness. The deposition steps 210 may include a dose step 201A in which a precursor gas is introduced into a deposition chamber. A purge step 203A (e.g., an evacuation step) removes most or all remaining precursor-gas molecules. An RF-application step 205A (e.g., an RF conversion step) may be added in which a plasma species allows reduction of a deposition temperature during plasma-assisted ALD (PEALD), followed by a plasma-species RF purge step 207A. The repeated process, including a dose step 201B, a purge step 203B, an RF-application step 205B, and a plasma-species RF purge step 207B, may be performed with an additional type or types of precursor gases. An entirety of the ALD oxidation process 200 may be repeated as often as desired to achieve a preselected final film thickness.

FIG. 2B shows an example of a graph 230 of deposition rate as a function of process steps selected in FIG. 2A. With concurrent reference to FIGS. 2A and 2B, various ones, or combinations of ones, of the steps in the ALD oxidation process 200 were considered in which to add the H₂ gas in order to increase the deposition rate (e.g., the deposition growth per cycle).

For example, referring now to FIG. 2B, a baseline normalized deposition rate 231 of approximately 0.85 is shown for comparison. In the baseline normalized deposition rate 231, no H₂ gas was added in any of the process steps of the ALD oxidation process 200. At a second deposition rate point 233, H₂ gas was added in all of the process steps described above, resulting in an improved normalized deposition rate of approximately 0.98 (e.g., roughly a 15% improvement over the baseline normalized deposition rate 231).

At a third deposition rate point 235, H₂ gas was added to react with bis(tertiarybutylamino) silane (BTBAS) to determine whether a precursor absorption would increase only during the dose step 201A of FIG. 2A. As noted in FIG. 2B, the third deposition rate point 235, with H₂ added during the dose step 201A, was found to be approximately equivalent with the deposition rate of the baseline normalized deposition rate 231.

At a fourth deposition rate point 237, H₂ gas was added only during the RF-application step 205A. During this RF conversion operation, H+ ions react with O-ions in an exothermic reaction, resulting in a more efficient oxidation process. As noted by the fourth deposition rate point 237 of the graph 230, the normalized deposition rate has increased to approximately 1.0, or approximately an 18% increase in deposition rate over the baseline normalized deposition rate 231.

As noted by the graph 230 at a fifth deposition rate point 239, H₂ gas was added during both the RF-application step 205A and the plasma-species RF purge step 207A. The fifth deposition rate point 239 of the graph 230 indicates that the normalized deposition rate remains at approximately 1.0, or approximately an 18% increase in deposition rate over the baseline normalized deposition rate 231. Therefore, adding H₂ gas during both the RF-application step 205A and the plasma-species RF purge step 207A did not increase the deposition rate significantly over adding H₂ gas only during the RF-application step 205A.

At a sixth deposition rate point 241, H₂ gas was added only during the plasma-species RF purge step 207A. Adding the H₂ gas during the RF purge step creates additional diatomic anion bonds of hydroxide (OH—) bonds, which help better absorb the precursor gas of BTBAS in this example. As indicated by the graph 230, the sixth deposition rate point 241 increased to a normalized deposition rate of approximately 0.87.

Based on the exemplary tests described above, and using BTBAS as a precursor, adding H₂ gas during the RF-application step 205A had a large increase in deposition rate over not using H₂ gas. Further, the large increase in deposition rate is coupled with a conservation of H₂ gas (and limiting related process-recipe changes) as would be required under adding H₂ gas during all deposition steps, as depicted by second deposition rate point 233. The large increase in deposition rate is also coupled with conserving H₂ gas otherwise added during both the RF-application step 205A and the plasma-species RF purge step 207A. Therefore, the large increase in deposition rate is accomplished by adding H₂ gas only during the RF-application step 205A.

Moreover, although not shown explicitly, each of the process steps described above, both with and without H₂ gas being introduced, was repeated over multiple deposition stations to verify repeatability of the process. The various tests verified excellent repeatability. Depending upon a selected precursor gas, a person of ordinary skill in the art will recognize that comparable results may be expected with other precursor gases as well. Based upon reading and understanding the disclosed subject matter, the person of ordinary skill in the art will recognize how to repeat such tests with a selected precursor gas.

Referring now to FIG. 3, an example of a graph 300 of a bivariate fit of thickness of a film as a function of flowrate of H₂ gas during a radio-frequency (RF) conversion step in an oxidation process is shown. The graph 300 reflects the fourth deposition rate point 237 of FIG. 2B in which H₂ gas was added only during the RF-application step 205A (see FIG. 2A). As indicated by the graph 300, an approximate thickness of a deposited film (e.g., silicon dioxide including one or both of SiO₂ and SiₓO_{y}) increases from about 183 Angstroms (Å) with an H₂-gas flowrate of zero standard cubic centimeters per minute (sccm), to about 200 Å with an H₂-gas flowrate of about 800 sccm, to about 210 Å with an H₂-gas flowrate of about 9000 sccm. As is further indicated by the graph 300, an H₂-gas flowrate of approximately 3000 sccm is saturating the deposition rate increase in film thickness. Stated another way, any additional increase in H₂-gas flowrate above 3000 sccm does not significantly increase the deposition rate of the film. It is expected that the graph 300 would not change significantly with changes in pedestal temperature or RF power. The bivariate fit of thickness of a film as a function of flowrate of H₂ gas is substantially dependent only on the partial pressure of the gas, which remains invariant.

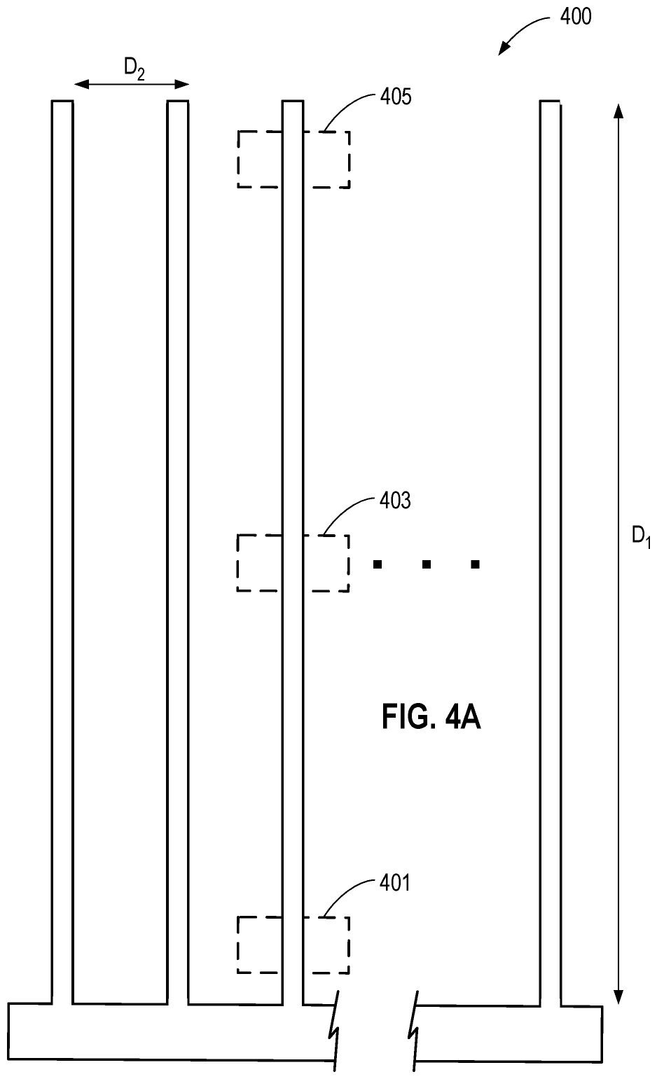

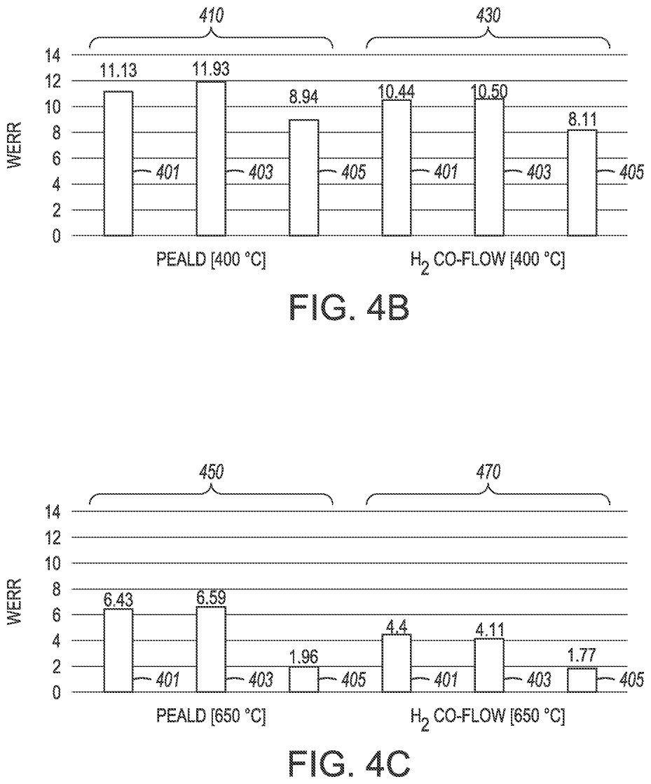

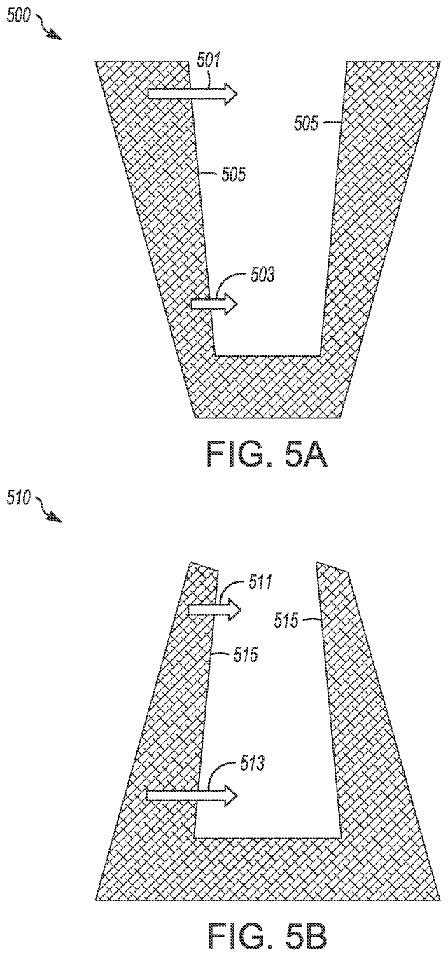

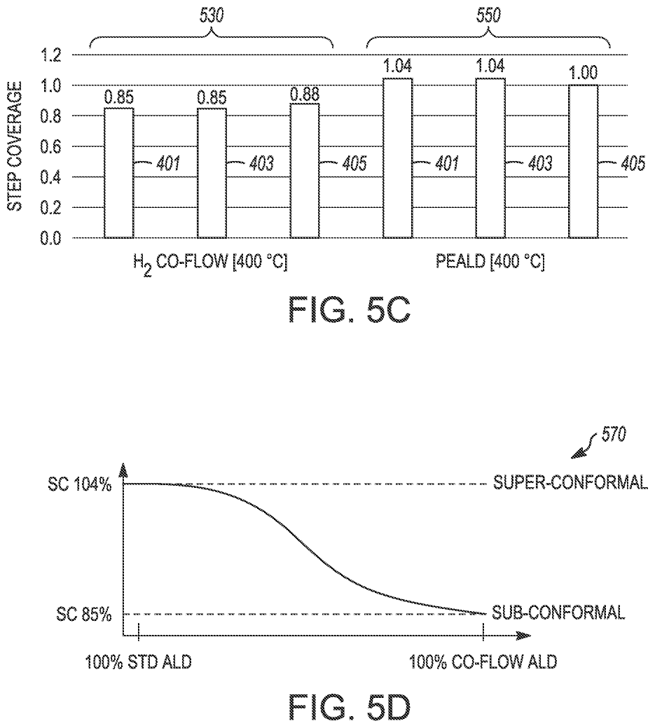

FIG. 4A shows an example of a cross-sectional view of a semiconductor structure 400 used to determine a wet-etch rate ratio (WERR) improvement due to an addition of H₂ gas. The example of the semiconductor structure 400 has an aspect ratio of approximately 30-to-1. In this particular example, the semiconductor structure 400 has features (e.g., devices) with an overall height, D₁, and a pitch, D₂. In this example, the pitch, D₂, is about 1/30^{th} the dimension of D₁. However, upon reading and understanding the disclosed subject matter, a person of ordinary skill in the art will recognize that various types of test structures with various aspect ratios may be used. A bottom highlighted-area 401, a middle highlighted-area 403, and a top highlighted-area 405 of the semiconductor structure 400 are described below to indicate an effect of forming a film with regard to both WERR and step coverage on the semiconductor structure 400 at the three different locational areas 401, 403, 405. However, a person of ordinary skill in the art will recognize that the semiconductor structure is provided as an example only of how the disclosed subject matter may be used with a variety of different semiconductor structures encountered in a semiconductor fabrication facility or another industry allied with or using components similar to the semiconductor industry (e.g., thin-film displays, disk-drive manufacturing, or even certain types of machining operations). The WERR and step coverage factors are described in detail below with reference to FIGS. 4A, 4B, and 5C. Each of the bottom highlighted-area 401, the middle highlighted-area 403, and the top highlighted-area 405 have an approximate height of about 0.5 μm.

FIGS. 4B and 4C show examples of graphs of WERR at various positions within the semiconductor structure of FIG. 4A. The graphs of FIGS. 4B and 4C compare a standard plasma-enhanced ALD (PEALD) process with an H₂-gas co-flow ALD process performed at temperatures of 400° C. and 650° C., respectively. The precursor gas used in the examples of FIGS. 4B and 4C was tris(dimethylamino) silane (SiH(N(CH₃)₂)₃ or TDMAS).

Specifically, FIG. 4B shows a graph 410 of a standard PEALD process (without an H₂-gas co-flow) and a graph 430 of a modified PEALD process with an H₂-gas co-flow indicating differences in WERR for each of the three locational areas, the bottom highlighted-area 401, the middle highlighted-area 403, and the top highlighted-area 405 of FIG. 4A. Each of the graphs 410, 430 in this example was prepared using the precursor BTBAS at a pedestal temperature of 400° C. The graph 430 shows the modified PEALD process, that includes the H₂-gas co-flow, indicating differences in WERR for each of the three locational areas, the bottom, middle, and top highlighted-areas 401, 403, 405. Adding the H₂-gas co-flow has improved the WERR from about 6% to about 12% at the pedestal temperature of about 400° C.

FIG. 4C shows a graph 450 of a standard PEALD process (without an H₂-gas co-flow) and a graph 470 of a modified PEALD process with an H₂-gas co-flow indicating differences in WERR for each of the three locational areas, the bottom highlighted-area 401, the middle highlighted-area 403, and the top highlighted-area 405 of FIG. 4A. Each of the graphs 450, 470 was prepared using the precursor BTBAS at a pedestal temperature of 650° C. The graph 470 shows the modified PEALD process, that includes the H₂-gas co-flow, indicating differences in WERR for each of the three locational areas, the bottom, middle, and top highlighted-areas 401, 403, 405. Adding the H₂-gas co-flow has improved the WERR from about 6% to about 12% at the pedestal temperature of about 650° C.

As noted, BTBAS was used as the precursor gas in preparing the graphs of FIGS. 4B and 4C. However, upon reading and understanding the disclosed subject matter, the person of ordinary skill in the art will recognize that similar results may be obtained with other types of precursor gases as well. Therefore, the examples provided herein for determining a WERR at different process conditions (e.g., pedestal temperature) are provided as examples only to more fully elucidate the disclosed subject matter.

FIGS. 5A and 5B show examples of sub-conformal 500 and super-conformal 510 step-coverage cross-sectional drawings, respectively. As described in more detail with reference to FIGS. 5C and 5D, below, the step coverage decreases with an H₂-gas co-flow. In a fully-conformal or nearly conformal deposition process, a deposited film is formed out from (or over) an existing, underlying structure in an approximately uniform film thickness regardless of differences in geometry of the structure.

As indicated by the sub-conformal step-coverage cross-sectional drawing 500, a deposition of a film 505 formed out from an upper-portion 501 of an underlying structure formed by ALD processes indicates a heavier deposition out from the upper-portion 501 as compared with a deposition formed out from a lower-portion 503 of the structure. The thicker deposition formed out from the upper-portion 501 compared with the thinner deposition formed out from the lower-portion 503 is indicative of a sub-conformal deposition process.

As indicated by the super-conformal step-coverage cross-sectional drawing 510 of FIG. 5B, a deposition of a film 515 formed out from an upper-portion 511 of an underlying structure formed by ALD processes indicates a thinner deposition out from the upper-portion 511 as compared with a deposition formed out from a lower-portion 513 of the structure. The thinner deposition formed out from the upper-portion 511 compared with the thinner deposition formed out from the lower-portion 513 is indicative of a super-conformal deposition process.

FIG. 5C shows examples of graphs of normalized step coverage at various positions within the semiconductor structure of FIG. 4A; the graphs compare an H₂-gas co-flow ALD process 530 with a standard PEALD process 550, for each of the three locational areas (the bottom highlighted-area 401, the middle highlighted-area 403, and the top highlighted-area 405 of FIG. 4A). Each of the graphs of FIG. 5C was constructed using a deposition pedestal temperature of approximately 400° C. As noted by the graph on the left showing an H₂-gas co-flow ALD process 530, the normalized step coverage is 0.85, 0.85, and 0.88 for each of the three locational areas of FIG. 4A, the bottom, middle, and top highlighted-areas 401, 403, 405, respectively.

In contrast to the graph on the left showing an H₂-gas co-flow ALD process 530, the graph on the right shows a standard PEALD process 550 without the H₂-gas co-flow. A normalized step coverage of the standard PEALD process 550 is 1.04, 1.04, and 1.00 for each of the three locational areas of FIG. 4A, the bottom, middle, and top highlighted-areas 401, 403, 405, respectively.

With continuing reference to FIG. 5C, and concurrent reference now to FIG. 5D, an exemplary graph 570 of super-conformal and sub-conformal step coverage as a function of a standard ALD process and various amounts of an H₂-gas co-flow ALD process in a gapfill operation is shown. As noted by the graphs of FIG. 5C, using an H₂-gas co-flow in various amounts can control the step coverage of a film from super-conformal, at up to about 104%, to sub-conformal, down to about 85%. Therefore, by combining an H₂-gas co-flow process with a standard PEALD process, the step coverage can be controlled from sub-conformal (less than 100%) to super-conformal (greater than 100%). Further, testing has shown that the step coverage can be controlled with little to no discernible impact on a quality level of the deposited film, or the quality of a gapfill performance. Furthermore, other testing with other types of precursor gases has indicated a 95% to 120% step coverage range.

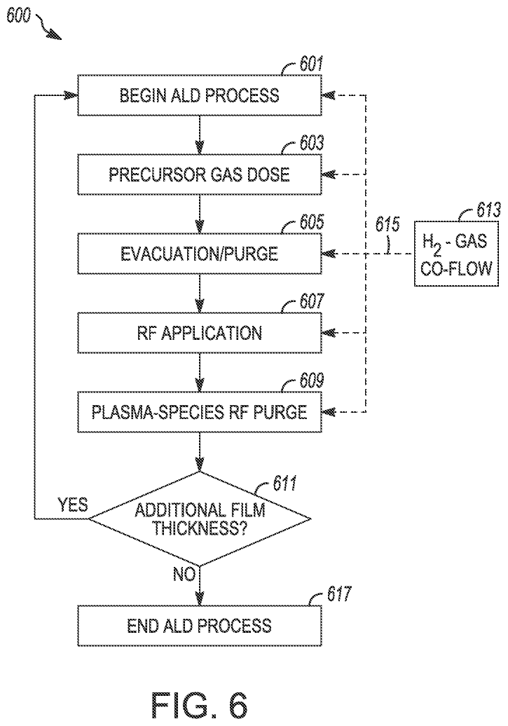

FIG. 6 shows an exemplary method 600 for conducting an ALD oxidation process using an H₂-gas co-flow. At operation 601, the ALD oxidation process is started. The ALD process may involve inserting a substrate into a deposition chamber (e.g., a plasma-based reaction chamber), pumping down the deposition chamber, preparing a process recipe (various examples of which and various means for executing the recipes are described in detail below), and other steps for starting the ALD process as is known in the art.

At operation 603, a precursor gas dose is introduced into a deposition chamber. The precursor gas remains in the deposition chamber for a predetermined time (at a predetermined pedestal temperature, with a predetermined radio-frequency (RF) power level, and other parameters known in the art). At operation 605, an evacuation or purge step removes most or all remaining precursor-gas molecules from the deposition chamber. At operation 607, an RF-application step (e.g., an RF conversion step) may be added in which a plasma species allows reduction during, for example, plasma-assisted ALD (PEALD), followed by a plasma-species RF purge step at operation 609.

At operation 611, a determination is made as to whether an additional film thickness is desired for a given process. If the determination is made that the film thickness is desired to be thicker, the ALD process starts again at operation 601 with the same precursor as used previously, or with one or more additional precursors. An entirety of the exemplary method 600 for conducting an ALD oxidation process may be repeated as often as desired to achieve a preselected final film thickness with desired film properties. If a determination is made at operation 611 that an additional film thickness is not desired, the ALD oxidation process ends at operation 617.

During the exemplary method 600 for the ALD oxidation process operations described above, a H₂-gas co-flow operation 613 may be added during one or more of the operations as shown by the optional H₂-gas co-flow operations 615. A determination as to how many and which of the operations to which the H₂-gas co-flow is added is discussed herein with reference to, for example, FIG. 2B.

Therefore overall, using the techniques of the disclosed subject matter provided herein, a deposition rate using an H₂-gas co-flow process is improved from approximately 10% to more than about 15% with a blanket film quality improvement of about 10% based on WERR. The quality of a sidewall WERR is improved from about 6% to about 35% (note that these ratios are partially dependent on a thermal budget as described above and tend to increase the sidewall WERR with higher temperatures). Additionally, the gapfill performance provides excellent control via a potential hybrid process of a standard PEALD process at least partially combined with an H₂-gas co-flow. The step coverage can be tuned, depending on an amount of H₂-gas co-flow, from approximately 85% to about 120% (normalized values) without compromising a quality of the deposited film.

As discussed in various examples above, the deposited film comprises silicon dioxide (e.g., SiO₂ or SiₓO_{y}). For silicon dioxide, various example embodiments described used TDMAS (also referred to as 3DMAS) of BTBAS simply to provide a context of a precursor gas. However, the same H₂-gas co-flow can be used with other silicon dioxide precursor gases such as diisopropylaminosilane (DIPAS), Silanediamine, N,N,N′,N′-tetraethyl (SAM24), or other suitable precursors. Further, as noted above, the disclosed subject matter is not limited to forming SiO₂ or SiₓO_{y} films only. Consequently, other types of precursor gases may be employed instead of or in addition to the precursor gases shown explicitly herein. The plasma-gas mixture may include Argon (Ar), oxygen (O₂), nitrogen (N₂), nitrous oxide (N₂O) or various combinations thereof, or other suitable plasma-gas mixtures. Also, various pedestal temperatures, RF energies, and dose times and flows may be used depending on a given process.

Such methods and various process recipes as described above may be run on various types of devices as described below in more detail. The devices include, for example, a computer or microprocessor, a special-purpose processor, such as a field programmable gate array (FPGA) or an application-specific integrated circuit (ASIC) that is programmed, in software, firmware, or as a hardware implementation, with one or more aspects of the disclosed subject matter described above.

Throughout this specification, plural instances may implement components, operations, or structures described as a single instance. Although individual operations of one or more methods are illustrated and described as separate operations, one or more of the individual operations may be performed concurrently, and nothing requires that the operations necessarily be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter described herein.

Certain embodiments or process recipes described herein may be performed using various types of logic or a number of components, modules, or mechanisms. Modules may constitute either software modules (e.g., code embodied on a machine-readable medium or in a transmission signal) or hardware modules. A “hardware module” is a tangible unit capable of performing certain operations and may be configured or arranged in a certain physical manner. In various embodiments, one or more computer systems (e.g., a standalone computer system, a client computer system, or a server computer system) or one or more hardware modules of a computer system (e.g., a processor or a group of processors) may be configured by software (e.g., an application or application portion) as a hardware module that operates to perform certain operations as described herein.

In some embodiments, a hardware module may be implemented mechanically, electronically, or any suitable combination thereof. For example, a hardware module may include dedicated circuitry or logic that is permanently configured to perform certain operations. For example, a hardware module may be a special-purpose processor, such as a field programmable gate array (FPGA) or an ASIC.

A hardware module may also include programmable logic or circuitry that is temporarily configured by software to perform certain operations. For example, a hardware module may include software encompassed within a general-purpose processor or other programmable processor. It will be appreciated that the decision to implement a hardware module mechanically, in dedicated and permanently configured circuitry, or in temporarily configured circuitry (e.g., configured by software) may be driven by cost and time considerations.

Accordingly, the phrase “hardware module” should be understood to encompass a tangible entity, be that an entity that is physically constructed, permanently configured (e.g., hardwired), or temporarily configured (e.g., programmed) to operate in a certain manner or to perform certain operations described herein. As used herein, “hardware-implemented module” refers to a hardware module. Considering embodiments in which hardware modules are temporarily configured (e.g., programmed), each of the hardware modules need not be configured or instantiated at any one instance in time. For example, where a hardware module comprises a general-purpose processor configured by software to become a special-purpose processor, the general-purpose processor may be configured as respectively different special-purpose processors (e.g., comprising different hardware modules) at different times. Software may accordingly configure a processor, for example, to constitute a particular hardware-module at one instance of time and to constitute a different hardware module at a different instance of time.

Hardware modules can provide information to, and receive information from, other hardware modules. Accordingly, the described hardware modules may be regarded as being communicatively coupled (e.g., to run one or more process recipes). Where multiple hardware modules exist contemporaneously, communications may be achieved through signal transmission (e.g., over appropriate circuits and buses) between or among two or more of the hardware modules. In embodiments in which multiple hardware modules are configured or instantiated at different times, communications between such hardware modules may be achieved, for example, through the storage and retrieval of information in memory structures to which the multiple hardware modules have access. For example, one hardware module may perform an operation and store the output of that operation in a memory device to which it is communicatively coupled. A further hardware module may then, at a later time, access the memory device to retrieve and process the stored output. Hardware modules may also initiate communications with input or output devices, and can operate on a resource (e.g., a collection of information).

The various operations of example methods and process recipes described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions described herein. As used herein, “processor-implemented module” refers to a hardware module implemented using one or more processors.

Similarly, the methods and process recipes, either explicitly or impliedly described herein, may be at least partially processor-implemented, a processor being an example of hardware. For example, at least some of the operations of a method may be performed by one or more processors or processor-implemented modules.

Moreover, the one or more processors may also operate to support performance of the relevant operations in a “cloud computing” environment or as a “software as a service” (SaaS). For example, at least some of the operations may be performed by a group of computers (as examples of machines including processors), with these operations being accessible via a network (e.g., the Internet) and via one or more appropriate interfaces (e.g., an application program interface (API)).

The performance of certain of the operations may be distributed among the one or more processors, not only residing within a single machine, but deployed across a number of machines. In some embodiments, the one or more processors or processor-implemented modules may be located in a single geographic location (e.g., within a home environment, an office environment, or a server farm). In other embodiments, the one or more processors or processor-implemented modules may be distributed across a number of geographic locations.

As used herein, the term “or” may be construed in an inclusive or exclusive sense. Further, other embodiments will be understood by a person of ordinary skill in the art upon reading and understanding the disclosure provided. Further, upon reading and understanding the disclosure provided herein, the person of ordinary skill in the art will readily understand that various combinations of the techniques and examples provided herein may all be applied in various combinations.

Although various embodiments are discussed separately, these separate embodiments are not intended to be considered as independent techniques or designs. As indicated above, each of the various portions may be inter-related and each may be used separately or in combination with other embodiments of the H₂-gas co-flow process discussed herein. For example, although various embodiments of methods, operations, and processes have been described, these methods, operations, and processes may be used either separately or in various combinations.

Consequently, many modifications and variations can be made, as will be apparent to a person of ordinary skill in the art upon reading and understanding the disclosure provided herein. Functionally equivalent methods and devices within the scope of the disclosure, in addition to those enumerated herein, will be apparent to the skilled artisan from the foregoing descriptions. Portions and features of some embodiments may be included in, or substituted for, those of others. Such modifications and variations are intended to fall within a scope of the appended claims.

Therefore, the present disclosure is to be limited only by the terms of the appended claims, along with the full scope of equivalents to which such claims are entitled. It is also to be understood that the terminology used herein is for the purpose of describing particular embodiments only and is not intended to be limiting.

The Abstract of the Disclosure is provided to allow the reader to ascertain quickly the nature of the technical disclosure. The abstract is submitted with the understanding that it will not be used to interpret or limit the claims.

In addition, in the foregoing Detailed Description, it may be seen that various features may be grouped together in a single embodiment for the purpose of streamlining the disclosure. This method of disclosure is not to be interpreted as limiting the claims. Thus, the following claims are hereby incorporated into the Detailed Description, with each claim standing on its own as a separate embodiment.

### THE FOLLOWING NUMBERED EXAMPLES ARE SPECIFIC EMBODIMENTS OF THE DISCLOSED SUBJECT MATTER

Example 1: An embodiment of the disclosed subject matter describes a Example 1: An embodiment of the disclosed subject matter describes a method for increasing a deposition rate of an atomic-layer deposition (ALD)-produced film onto a surface of a substrate. The method includes placing the substrate in a deposition chamber; introducing a precursor gas into the deposition chamber; evacuating at least a portion of remaining precursor-gas molecules from the deposition chamber; applying a radio-frequency (RF) conversion to the substrate in the deposition chamber; performing a plasma-species RF purge; and introducing a hydrogen (H₂) gas into the deposition chamber during one or more of introducing the precursor gas into the deposition chamber, evacuating at least the portion of remaining precursor-gas molecules from the deposition chamber, applying the RF conversion step to the substrate in the deposition chamber, and performing the plasma-species RF purge.

Example 2: The method of Example 1, further including making a determination whether an additional ALD-produced film thickness is desired for a given process. Based on a determination that the additional ALD-produced film thickness is desired, repeating at least once the operations of introducing the precursor gas into the deposition chamber, evacuating at least the portion of remaining precursor-gas molecules from the deposition chamber, applying the RF conversion step to the substrate in the deposition chamber, and performing the plasma-species RF purge, and introducing the hydrogen gas into the deposition chamber during at least one of these operations. Based on a determination that the additional ALD-produced film thickness is not desired, ending the method.

Example 3: The method of either Example 1 or Example 2, wherein the precursor gas is selected to form the film comprising an oxidation layer onto the surface of the substrate.

Example 4: The method of any one of the preceding Examples, wherein the precursor gas is selected to form the film comprising an oxide layer onto the surface of the substrate.

Example 5: The method of any one of the preceding Examples, wherein the surface of the substrate includes various features.

Example 6: The method of any one of the preceding Examples, wherein the method is used with low-aspect ratio features.

Example 7: The method of any one of the preceding Examples, wherein the method is used with high-aspect ratio features.

Example 8: The method of any one of the preceding Examples, wherein the RF-conversion is configured to create diatomic anion bonds of hydroxide (OH—) bonds

Example 9: The method of any one of the preceding Examples, wherein a flowrate of the introduced H₂ gas is about 800 standard cubic centimeters per minute (sccm).

Example 10: The method of any one of the preceding Examples, wherein a flowrate of the introduced H₂ gas is about 3000 standard cubic centimeters per minute (sccm).

Example 11: The method of any one of the preceding Examples, wherein the introduced hydrogen gas is provided as an H₂-gas co-flow with other process gases into the deposition chamber.

Example 12: The method of any one of the preceding Examples, wherein the H₂ gas is introduced to react with tris(dimethylamino) silane (SiH(N(CH3)2)3 (TDMAS).

Example 13: The method of any one of the preceding Examples, wherein the H₂ gas is introduced to react with bis(tertiarybutylamino) silane (BTBAS)

Example 14: The method of any one of the preceding Examples, wherein the precursor gas includes at least one gas selected from gases including diisopropylaminosilane (DIPAS) and Silanediamine, N,N,N′,N′-tetraethyl (SAM24)

Example 15: The method of any one of the preceding Examples, further including introducing a plasma-gas mixture as an H₂-gas co-flow into the deposition chamber, the plasma-gas mixture including at least one gas type selected from gases including Argon (Ar), oxygen (O₂), nitrogen (N₂), and nitrous oxide (N₂O).

Example 16: The method of any one of the preceding Examples, wherein introducing the H₂ gas is performed to improve a wet-etch rate ratio over an ALD process not using an H₂-gas co-flow.

Example 17: The method of any one of the preceding Examples, further including tuning a step coverage of the ALD-produced film by adjusting an amount of the H₂ gas introduced into the deposition chamber.

Example 18: An embodiment of the disclosed subject matter describes a method for increasing a deposition rate of an atomic-layer deposition (ALD)-produced oxide film on a substrate. The method includes placing the substrate in a deposition chamber; introducing a precursor gas into the deposition chamber; evacuating at least a portion of remaining precursor-gas molecules from the deposition chamber; applying a radio-frequency (RF) conversion to the substrate in the deposition chamber; performing a plasma-species RF purge; and introducing hydrogen (H₂) gas into the deposition chamber as an H₂ co-flow gas during at least one of the applying of the RF conversion and the performing of the plasma-species RF purge.

Example 19: The method of Example 18, wherein the H₂-gas co-flow is introduced only during the RF conversion.

Example 20: The method of either Example 18 or Example 19, wherein introducing the H₂ gas is performed to improve a wet-etch rate ratio over a process not using an H₂-gas co-flow.

Example 21: The method of any one of Example 18 through Example 20, further including tuning a step coverage of the ALD-produced oxide film from approximately 85% to about 120% by adjusting an amount of the H₂-gas introduced into the deposition chamber.

Example 22: An embodiment of the disclosed subject matter describes a method for increasing a deposition rate of an atomic-layer deposition (ALD)-produced silicon dioxide film on a substrate. The method includes placing the substrate in a deposition chamber; introducing a precursor gas into the deposition chamber; evacuating at least a portion of remaining precursor-gas molecules from the deposition chamber; applying a radio-frequency (RF) conversion to the substrate in the deposition chamber; performing a plasma-species RF purge; and introducing a hydrogen (H₂) gas into the deposition chamber only during the applying of the RF conversion.

Example 23: The method of Example 22, wherein introducing the H₂ gas is performed to improve a wet-etch rate ratio over a process not using an H₂-gas co-flow.

Example 24: The method of either Example 22 or Example 23, further including introducing a plasma-gas mixture as an H₂-gas co-flow into the deposition chamber. The plasma-gas mixture includes at least one gas type selected from gases including Argon (Ar), oxygen (O₂), nitrogen (N₂), and nitrous oxide (N₂O).

Example 25: The method of any one of Example 22 through Example 24, further including tuning a step coverage of the ALD-produced silicon dioxide film by adjusting a ratio of the H₂ gas to the plasma-gas mixture introduced into the deposition chamber.

What is claimed is:

1. A method for increasing a deposition rate of an atomic-layer deposition (ALD)-produced film onto a surface of a substrate, the method comprising:
placing the substrate in a deposition chamber;
introducing a precursor gas into the deposition chamber;
evacuating at least a portion of remaining precursor-gas molecules from the deposition chamber;
applying a radio-frequency (RF) conversion to the substrate in the deposition chamber;
performing a plasma-species RF purge; and
introducing a hydrogen (H₂) gas into the deposition chamber during one or more of introducing the precursor gas into the deposition chamber, evacuating at least the portion of remaining precursor-gas molecules from the deposition chamber, applying the RF conversion step to the substrate in the deposition chamber, and performing the plasma-species RF purge.

2. The method of claim 1, further comprising:
making a determination whether an additional ALD-produced film thickness is desired for a given process;
based on a determination that the additional ALD-produced film thickness is desired, repeating at least once the operations of introducing the precursor gas into the deposition chamber, evacuating at least the portion of remaining precursor-gas molecules from the deposition chamber, applying the RF conversion step to the substrate in the deposition chamber, and performing the plasma-species RF purge, and introducing the hydrogen gas into the deposition chamber during at least one of these operations; and
based on a determination that the additional ALD-produced film thickness is not desired, ending the method.

3. The method of claim 1, wherein the precursor gas is selected to form the film comprising an oxidation layer onto the surface of the substrate.

4. The method of claim 1, wherein the precursor gas is selected to form the film comprising an oxide layer onto the surface of the substrate.

5. The method of claim 1, wherein the surface of the substrate includes various features.

6. The method of claim 1, wherein the method is used with low-aspect ratio features.

7. The method of claim 1, wherein the method is used with high-aspect ratio features.

8. The method of claim 1, wherein the RF-conversion is configured to create diatomic anion bonds of hydroxide (OH—) bonds

9. The method of claim 1, wherein a flowrate of the introduced H₂ gas is about 800 standard cubic centimeters per minute (sccm).

10. The method of claim 1, wherein a flowrate of the introduced H₂ gas is about 3000 standard cubic centimeters per minute (sccm).

11. The method of claim 1, wherein the introduced hydrogen gas is provided as an H₂-gas co-flow with other process gases into the deposition chamber.

12. The method of claim 1, wherein the H₂ gas is introduced to react with tris(dimethylamino) silane (SiH(N(CH3)2)3 (TDMAS).

13. The method of claim 1, wherein the H₂ gas is introduced to react with bis(tertiarybutylamino) silane (BTBAS)

14. The method of claim 1, wherein the precursor gas includes at least one gas selected from gases including diisopropylaminosilane (DIPAS) and Silanediamine, N,N,N′,N′-tetraethyl (SAM24)

15. The method of claim 1, further comprising introducing a plasma-gas mixture as an H₂-gas co-flow into the deposition chamber, the plasma-gas mixture including at least one gas type selected from gases including Argon (Ar), oxygen (O₂), nitrogen (N₂), and nitrous oxide (N₂O).

16. The method of claim 1, wherein introducing the H₂ gas is performed to improve a wet-etch rate ratio over an ALD process not using an H₂-gas co-flow.

17. The method of claim 1, further comprising tuning a step coverage of the ALD-produced film by adjusting an amount of the H₂ gas introduced into the deposition chamber.

18. A method for increasing a deposition rate of an atomic-layer deposition (ALD)-produced oxide film on a substrate, the method comprising:
placing the substrate in a deposition chamber;
introducing a precursor gas into the deposition chamber;
evacuating at least a portion of remaining precursor-gas molecules from the deposition chamber;
applying a radio-frequency (RF) conversion to the substrate in the deposition chamber;
performing a plasma-species RF purge; and
introducing hydrogen (H₂) gas into the deposition chamber as an H₂ co-flow gas during at least one of the applying of the RF conversion and the performing of the plasma-species RF purge.

19. The method of claim 18, wherein the H₂-gas co-flow is introduced only during the RF conversion.

20. The method of claim 18, wherein introducing the H₂ gas is performed to improve a wet-etch rate ratio over a process not using an H₂-gas co-flow.

21. The method of claim 18, further comprising tuning a step coverage of the ALD-produced oxide film from approximately 85% to about 120% by adjusting an amount of the H₂-gas introduced into the deposition chamber.

22. A method for increasing a deposition rate of an atomic-layer deposition (ALD)-produced silicon dioxide film on a substrate, the method comprising:
placing the substrate in a deposition chamber;
introducing a precursor gas into the deposition chamber;
evacuating at least a portion of remaining precursor-gas molecules from the deposition chamber;
applying a radio-frequency (RF) conversion to the substrate in the deposition chamber;
performing a plasma-species RF purge; and
introducing a hydrogen (H₂) gas into the deposition chamber only during the applying of the RF conversion.

23. The method of claim 22, wherein introducing the H₂ gas is performed to improve a wet-etch rate ratio over a process not using an H₂-gas co-flow.

24. The method of claim 22, further comprising introducing a plasma-gas mixture as an H₂-gas co-flow into the deposition chamber, the plasma-gas mixture including at least one gas type selected from gases including Argon (Ar), oxygen (O₂), nitrogen (N₂), and nitrous oxide (N₂O).

25. The method of claim 22, further comprising tuning a step coverage of the ALD-produced silicon dioxide film by adjusting a ratio of the H₂ gas to the plasma-gas mixture introduced into the deposition chamber.
